(19) United States
(12) Patent Application Publication
(10) Pub. No.: US 2017/0027070 A1
(43) Pub. Date: Jan. 26, 2017

(54) HOUSING ASSEMBLY OF A POWER OPERATED DEVICE AND METHOD OF MANUFACTURING THEREOF

(71) Applicant: Magna Closures Inc., Newmarket (CA)

(72) Inventors: Abdullah Siddiqui, North York (CA); Neil Guillermo, Richmond Hill (CA); Uzochukwu Okeke, Bradford (CA); Kar Wang Woo, Markham (CA)

(21) Appl. No.: 15/196,086

(22) Filed: Jun. 29, 2016

Related U.S. Application Data
(60) Provisional application No. 62/196,025, filed on Jul. 23, 2015.

(51) Int. Cl. H05K 5/02; H05K 1/09; H05K 3/24; H02K 5/04; H05K 3/10

(52) U.S. Cl. CPC H05K 5/0247; H02K 5/04; H05K 3/105; H05K 3/246; H05K 1/09

(57) ABSTRACT

A housing assembly for a power operated device and method of manufacturing the housing assembly are disclosed. The housing assembly includes a housing body with a motor platform and a switch platform and a connector platform each extending upwardly from the housing body. A connector is attached to the housing body in engagement with the connector platform and includes a plurality of connector terminals electrically connected to the connector platform. A plurality of traces are formed by laser directed structuring on the housing body and are electrically connected to and extend from the switch and motor platforms to the connector platform. A motor engages the motor platform for moving components of the power operated device and a switch engages the switch platform to detect the position of the components.

### CROSS-REFERENCE TO RELATED APPLICATIONS

This application claims the benefit of U.S. Provisional Application No. 62/196,025 filed Jul. 23, 2015. The entire disclosure of the above application is incorporated herein by reference.

### FIELD

The present disclosure relates generally to a housing assembly of a power operated device and a method of manufacturing the housing assembly of the power operated device.

### BACKGROUND

This section provides background information related to the present disclosure which is not necessarily prior art.

Housings for power operated devices frequently include attached wiring or printed circuit board assemblies for providing power and/or control interfaces to electrical components such as sensors, switches, motors, and actuators within the housing. To manufacture door latch housings for example, electrical traces necessary to power one or more motors and to connect switches within the housing are made by stamping copper sheet metal into traces and then over molding the traces to make a panel or board which is then attached to the housing. Motors and switches may be soldered to or engage pins or contacts on the panel. Because the copper sheet metal is stamped (i.e. a subtractive manufacturing process in which material is removed), the stamping process inherently produces residual waste which needs to be recycled and retreated into sheet metal to use again. Additionally, adding a panel or circuit board to a housing assembly increases the complexity and weight and can introduce manufacturing challenges due to issues such as additional assembly time, tolerance stack-up, and/or required mistake-proofing. Accordingly, there exists a need for an improved housing for a power operated device and a method of manufacturing the housing.

### SUMMARY

This section provides a general summary of the present disclosure and is not intended to be interpreted as a comprehensive disclosure of its full scope or all of its features, aspects and objectives.

Accordingly, it is an aspect of the present disclosure to provide a housing assembly of a power operated device including a housing body for securing and attaching components of the power operated device. At least one contact platform is coupled to the housing body. A connector is attached to the housing body and defines an inner cavity and includes a plurality of connector terminals disposed in the inner cavity. A trace substrate is coupled to the housing body and includes a plurality of traces formed on the trace substrate and electrically connected to and extending from the at least one contact platform to the connector.

According to another aspect of the disclosure, a housing assembly for a power operated device is provided. The housing assembly includes a trace substrate including a plurality of traces formed on the trace substrate by a molded interconnect technology. A connector is coupled to the trace substrate and includes a plurality of connector terminals. A motor platform is coupled to the trace substrate for coupling to a motor adapted to electrically connect to the plurality of traces to move components of the power operated device. A switch platform is coupled to the trace substrate for coupling to a switch adapted to electrically connect to the plurality of traces to detect one of movement and position of the components.

According to yet another aspect of the disclosure, a method of manufacturing a housing assembly of a power operated device is provided. The method includes the step of molding a trace substrate. The method proceeds by writing a plurality of conductive paths onto the trace substrate using a laser. The next step of the method is plating the conductive paths to form traces.

These and other aspects and areas of applicability will become apparent from the description provided herein. The description and specific examples in this summary are intended for purpose of illustration only and are not intended to limit the scope of the present disclosure.

### DRAWINGS

The drawings described herein are for illustrative purposes only of selected embodiments and not all implementations, and are not intended to limit the present disclosure to only that actually shown. With this in mind, various features and advantages of example embodiments of the present disclosure will become apparent from the following written description when considered in combination with the appended drawings, in which:

FIG. 1 is a perspective view of a closure panel system of a vehicle illustrating a latch assembly;

FIG. 2 is a partial top view of a housing assembly of a power operated device according to an aspect of the disclosure;

FIG. 3 is a partial top view of the housing assembly according to an aspect of the disclosure illustrating a motor and a switch;

FIG. 4 is a perspective view of a housing assembly of a power operated device according to an aspect of the disclosure illustrating a protopaint;

FIG. 5 is a partial perspective view of a housing assembly of a power operated device according to an aspect of the disclosure;

FIG. 6 is a perspective view of a cartridge of a housing assembly according to an aspect of the disclosure;

FIG. 7 is front view of the housing assembly of FIG. 5;

FIG. 8 is a perspective view of the housing assembly of FIG. 5; and

FIGS. 9-10 are flowcharts illustrating the steps of manufacturing a housing assembly of a power operated device according to an aspect of the disclosure.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to housing assemblies used for various power operated devices of the type well-suited for use in many applications. The housing assembly of this disclosure will be described in conjunction with one or more example embodiments. However, the specific example embodiments disclosed are merely provided to describe the inventive concepts, features, advantages and objectives will sufficient clarity to permit those skilled in this art to understand and practice the disclosure.

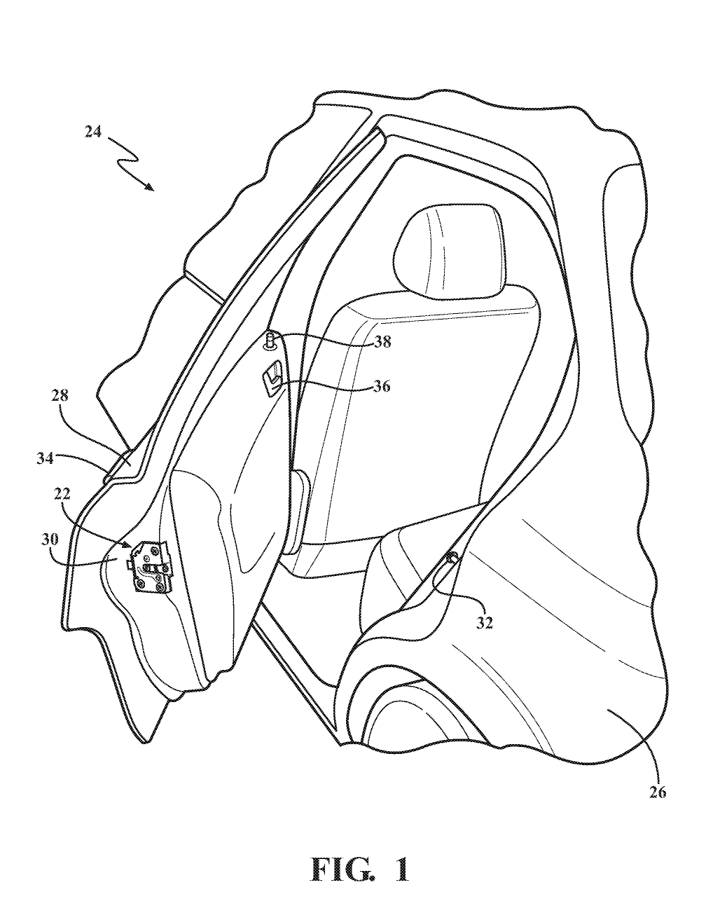

Referring to the Figures, wherein like numerals indicate corresponding parts throughout the several views, a housing assembly 20 used for a latch assembly 22 of a closure system is disclosed. FIG. 1 is a perspective view of a vehicle 24 that includes a vehicle body 26 and at least one vehicle door 28 (also referred to as closure panel 28). The vehicle door 28 includes the latch assembly 22 that is positioned on an edge face 30 and which is releasably engageable with a striker 32 on the vehicle body 26 to releasably hold the vehicle door 28 in a closed position. An outside door handle 34 and an inside door handle 36 are provided for opening the latch assembly 22 (i.e. for releasing the latch assembly 22 from the striker 32) to open the vehicle door 28. An optional lock knob 38 is shown and provides a visual indication of the lock state of the latch assembly 22 and may be operable to change the lock state between an unlocked position and a locked position.

The closure panel 28 (e.g. occupant ingress or egress controlling panels such as but not limited to vehicle doors 28 and lift gates/hatches) is connected to the vehicle body 26 via one or more hinges (not shown) and the latch assembly 22 (e.g. for retaining the closure panel 28 in a closed position once closed). Although the latch assembly 22 can be mounted to the closure panel 28 and the mating latch component can be mounted on the body, it should be understood that the closure panel 28 could instead have a mating latch component (e.g. striker 32) mounted thereon for coupling with a respective latch assembly 22 (e.g. with a ratchet component of the latch assembly 22) mounted on the vehicle body 26 (not shown). It should be appreciated that while the housing assembly 20 may be used as part of a latch assembly 22 for a vehicle door 26, it may also be used for other power operated devices such as, but not limited to electronic control units.

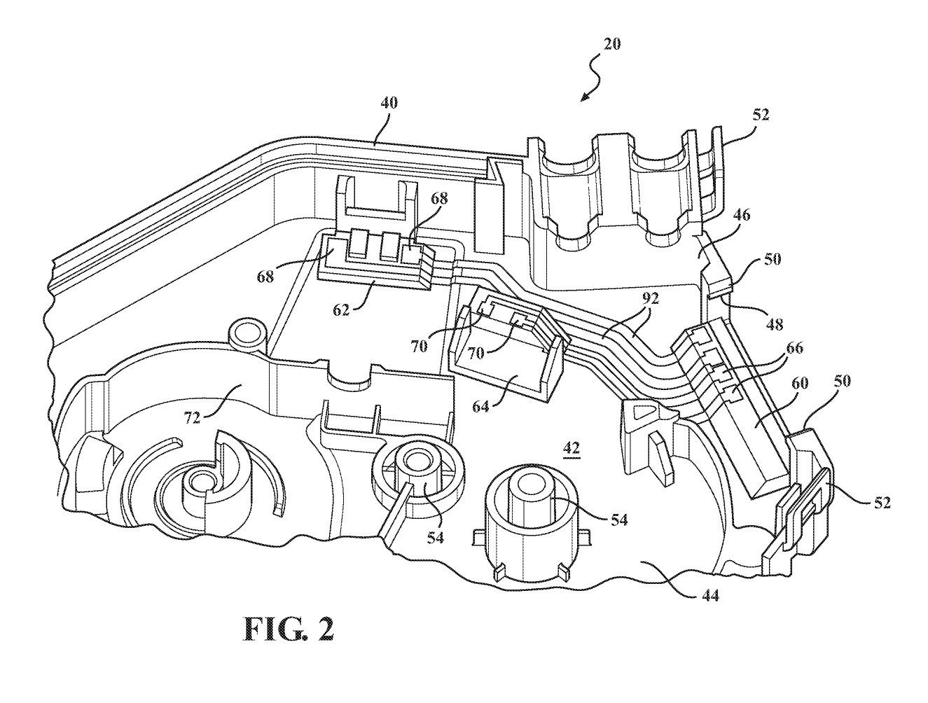

As best shown in FIG. 2, the housing assembly 20 for a power operated device includes a housing body 40 having a back plate 42 defining a top surface 44 and a bottom surface. The housing body 40 includes a first peripheral wall 46 disposed about an outer periphery of the back plate 42 and extending upwardly from the top surface 44 of the back plate 42. The first peripheral wall 46 defines a U-shaped passageway 48 and a pair of barbs 50 extending into the passageway 48. A plurality of locking tabs 52 also extend upwardly from the first peripheral wall 46. The housing body 40 further includes a plurality of support columns 54 attached to and extending upwardly from the top surface 44 of the back plate 42 for securing and attaching components of the power operated device (e.g. gears, ratchets, actuators). Additionally, the housing body 40 includes a side wall (not shown) attached to and extending downwardly from the bottom surface of the back plate 42 to define a shoulder extending along a side of the housing body 40. The side wall 56 also defines a second peripheral wall (not shown) disposed about an outer edge of the side wall.

The housing body 40 includes a plurality of contact platforms including a motor platform 62 and a switch platform 64 each extending upwardly from the top surface 44 of the housing body 40. A connector platform 60 also extends upwardly from the top surface 44 of the housing body 40 and includes a plurality of connector pads 66. Similarly, the motor platform 62 includes a pair of motor pads 68 and the switch platform 64 includes a pair of switch pads 70.

The housing body 40 also includes a first intermediate wall 72 extending upwardly from the top surface 44 of the housing body 40 and extending circuitously from the shoulder to the switch platform 64. A second intermediate wall 74 extends upwardly from the top surface 44 of the housing body 40 and extends from the first peripheral wall 46 adjacent the passageway 48. It should be understood that the housing body 40 may include intermediate walls configured differently than described above and illustrated in the Figures, include additional intermediate walls, or omit the intermediate walls 72, 74.

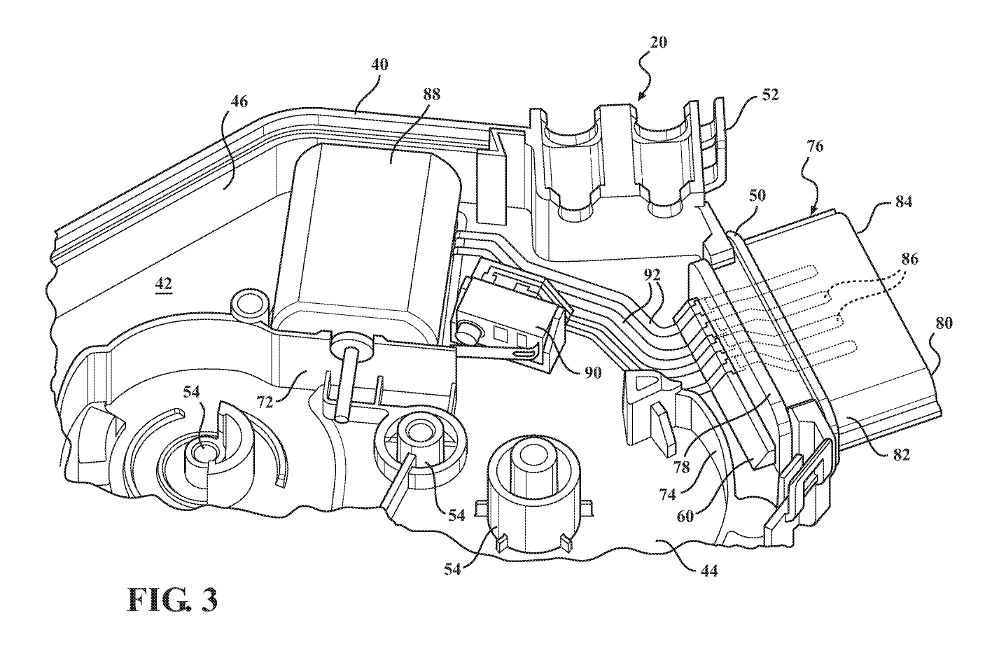

As best shown in FIG. 3, a connector 76 that is cup shaped and has a partially closed proximal end 78 and an open distal end 80 and a connector wall 82 extending from the proximal end 78 to the distal end 80 to define an inner cavity 84. The connector 76 attaches to the housing body 40 and includes a plurality of connector terminals 86 disposed in the inner cavity 84 and extending through the proximal end 78 toward the distal end 80 for electrically connecting to the connector pads 66. The connector wall 82 defines a slot adjacent the proximal end 78 and extending circumferentially around the connector 76 for engaging the first peripheral wall 46 of the housing body 40. The engagement of the slot of the connector wall 82 and the first peripheral wall 46 secures the connector 76 to the housing body 40 and the connector terminals 86 against the connector pads 66 as the barbs 50 lock the connector 76 into the passageway 48. According to an aspect, the connector 76 may engage a corresponding mating connector of a vehicle wiring harness in order to electrically connect the housing assembly 20 to other components and modules on the vehicle 24. It should be appreciated that the housing assembly 20 may include a connector 76 attached, configured or oriented in a different manner than described above and/or the connector 76 may be omitted from the housing assembly 20.

A motor 88 has a pair of motor 88 terminals for engagement with the motor pads 68 of the motor platform 62 and is disposed between the first peripheral wall 46 and the first intermediate wall 72. A switch 90 has a pair of switch terminals for engagement with the switch pads 70 of the switch platform 64 and is disposed on the switch platform 64. It should be appreciated that the housing assembly 20 may contain any number of motors 88 and/or switches 90, including zero, according to an aspect of the disclosure. According to another aspect, the motor 88 may be used to move the components of the power operated device and the switch 90 may be used to detect movement or position of the components. It should also be understood that the motor 88 and/or switch 90 may be oriented differently than described above and illustrated in the Figures.

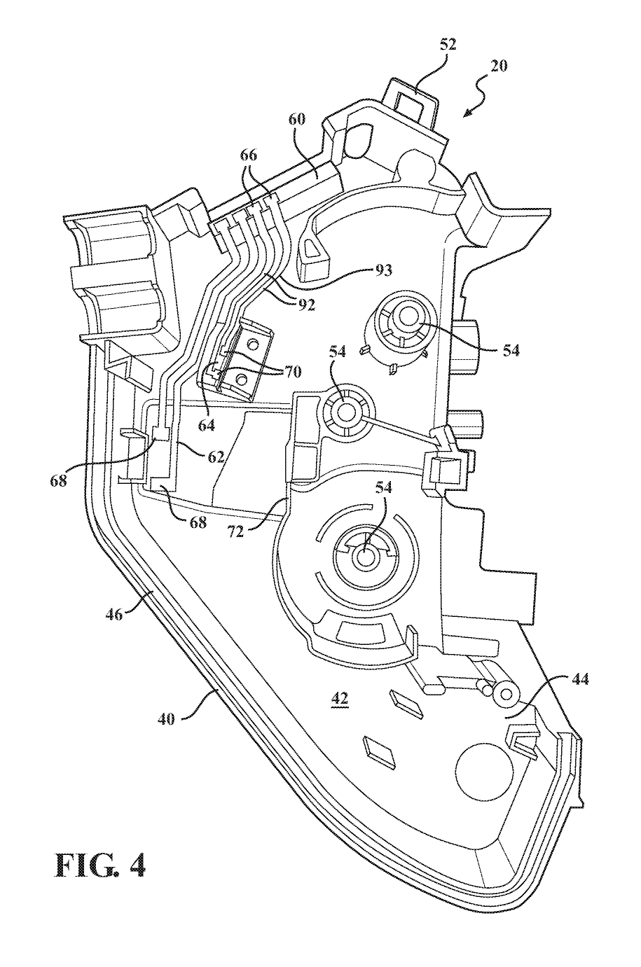

A plurality of traces 92 extend along the top surface 44 of the housing body 40 (i.e. trace substrate) from the switch pads 70 of the switch platform 64 and the motor pads 68 of the motor platform 62 to the connector pads 66 of the connector platform 60 for electrically interconnecting the motor 88 and the switch 90 with the connector terminals 86. Although the traces 92 can extend along the top surface 44 of the housing body 40, it should be appreciated that the traces 92 may also be disposed on other surfaces such as, but not limited to the bottom surface of the housing body 40 or at least one side of the intermediate walls 72, 74. According to an aspect, the housing body 40 can be a molded interconnect device (MID), in other words, an injection-molded thermoplastic part with integrated circuit traces 92. More specifically, the housing body 40 and traces 92 can be manufactured by what is known as a one-shot molding, or laser directed structuring in which the thermoplastic material of the housing body 40 is doped with a metal-plastic additive which can be activated by a laser and plated or metallized. However, it should be appreciated that the housing body 40 and traces 92 of the housing assembly 20 may instead be formed by another type of molded interconnect device technology, such as, but not limited to a two-shot molding method with two different thermoplastic resins with only one being platable (e.g. used in the areas where traces 92 are desired) or laser direct removing, also known as microscopic integrated processing technology (MIPTEC). According to an aspect, the traces 92 may also be formed using a protopaint 93 or conductive material, such as, but not limited to LPKF ProtoPaint LDS manufactured by LPKF Laser & Electronics AG which can be sprayed or otherwise applied to the entire housing body 40 or a portion thereof (e.g. where the traces 92 are desired), as illustrated in FIG. 4. Similar to the doped thermoplastic described above, the conductive material or protopaint 93 may then be activated with a laser and metallized. However, by using protopaint 93, the housing body 40 may be manufactured from other types of thermoplastic or other materials which do not need to be doped with a metal-plastic additive since it is the protopaint 93 applied to the housing body 40 that is activated by the laser, rather than the housing body 40 itself. The dimensions of the traces 92 may be varied depending on the amount of electrical current the trace 92 must carry. For example, a typical thickness of the traces 92 may be approximately 8-10 μm. Because the traces 92 or conductive paths are formed directly on the housing body 40, the housing assembly 20 does not require a separate printed circuit board or panel with traces 92 to be utilized. Additionally, there is no need to stamp the electrical traces 92 necessary to power the motor 88 and to connect the switch 90 within the housing assembly 20 from copper sheet metal. Therefore, no residual waste is produced from the stamping process that may need to be recycled and retreated into sheet metal to use again.

A cap (not shown) may be adapted to engage the housing body 40 and the locking tabs 52 for moving the switch terminals into engagement with the switch pads 70 and for securing the motor terminals against the motor pads 68 and for covering the components of the power operated device. Consequently, it may not be necessary to use a solder process in order to electrically connect the motor 88 and/or switch 90 to the traces 92. However, it should be appreciated that the switch terminals and/or motor terminals may also be soldered to the switch pads 70 and motor pads 68 respectively.

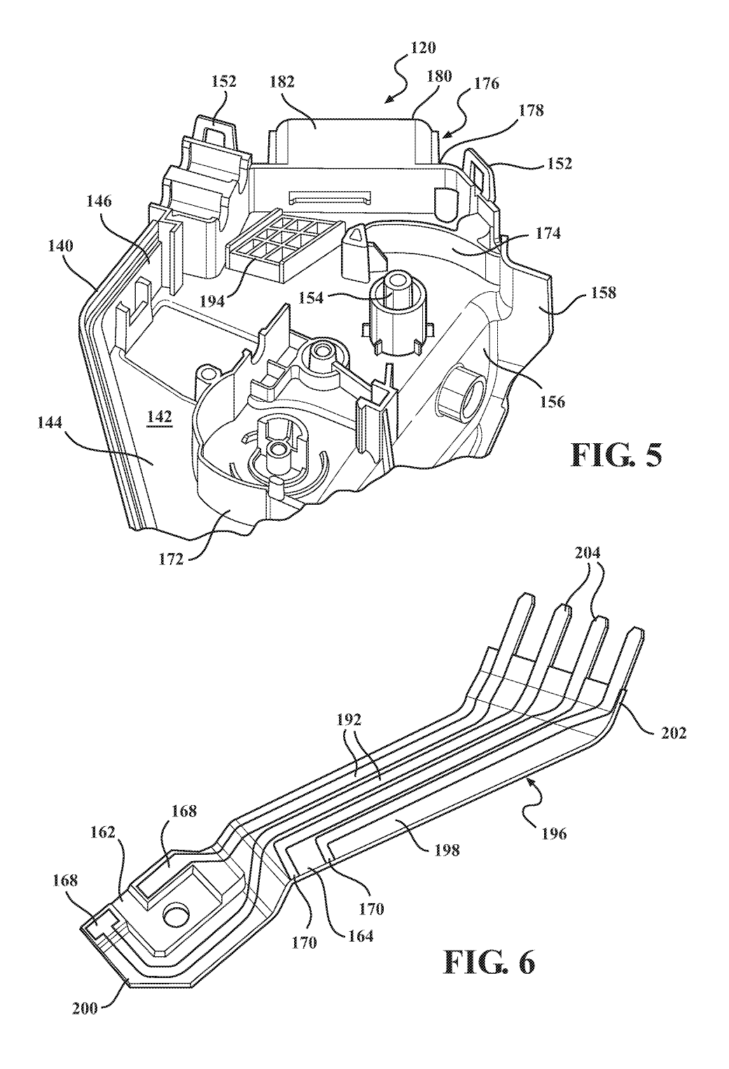

According to another aspect of the disclosure, a housing assembly 120 for a power operated device is illustrated in FIG. 5 includes a housing body 140 having a back plate 142 with a top surface 144 and a bottom surface. Similar to that described above, the housing body 140 includes a first peripheral wall 146 disposed about an outer periphery of the back plate 142 and extending upwardly from the top surface 144 of the back plate 142. A plurality of locking tabs 152 also extend upwardly from the first peripheral wall 146. The housing body 140 further includes a plurality of support columns 154 attached to and extending upwardly from the top surface 144 of the back plate 142 for securing and attaching components of the power operated device. Additionally, the housing body 140 includes a side wall 156 attached to and extending downwardly from the bottom surface of the back plate 142 to define a shoulder extending along a side of the housing body 140. The side wall 156 also defines a second peripheral wall 158 disposed about an outer edge of the side wall 156. The housing body 140 further includes a raised platform 194 attached to and extending upwardly from the top surface 144 of the back plate 142.

A connector 176 that is cup-shaped has a partially closed proximal end 178 and an open distal end 180 and a connector wall 182 extending from the proximal end 178 to the distal end 180 to define an inner cavity 184. The connector wall 182 is attached to and extends from the first peripheral wall 146 of the housing body 140.

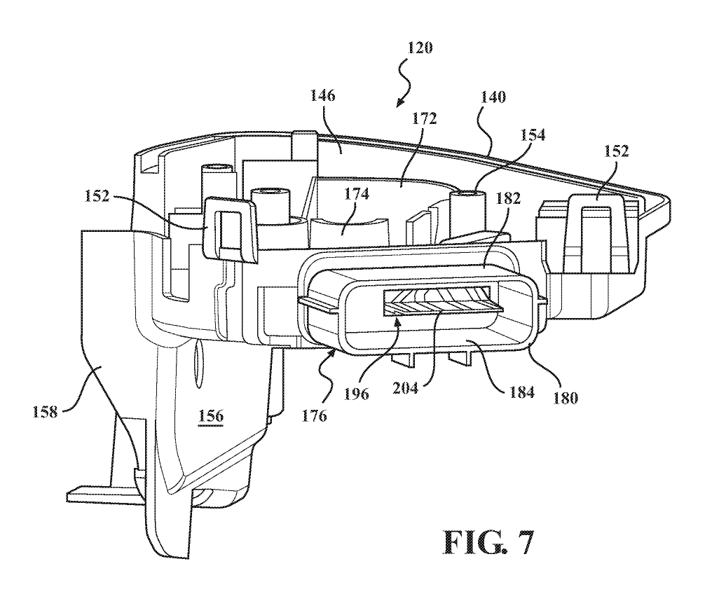

As best shown in FIG. 6, a cartridge 196 has an upper surface 198 and a lower surface and extends from a first end 200 to a second end 202 and is disposed on the raised platform 194 of the housing body 140. According to an aspect, the housing body 140 may also include molded locators to ensure that the cartridge 196 remains on the raised platform 194. The second end 202 of the cartridge 196 extends into the inner cavity 184 of the connector 176 through the proximal end 178 of the connector 176 as shown in FIG. 7. The cartridge 196 includes a plurality of cartridge terminals 204 extending from the second end 202 of the cartridge 196 and disposed in the inner cavity 184 and extending toward the distal end 180 of the connector 176. The cartridge 196 also includes a motor platform 162 (FIG. 5) disposed on the upper surface 198 of the cartridge 196 that includes a pair of motor pads 168. The cartridge 196 also includes a switch platform 164 (FIG. 5) on the upper surface 198 of the cartridge 196 that includes a pair of switch pads 170. According to an aspect, a motor (not shown) having a pair of motor terminals may engage the motor pads 168 of the motor platform 162 and be disposed between the first peripheral wall 146 and the first intermediate wall 172.

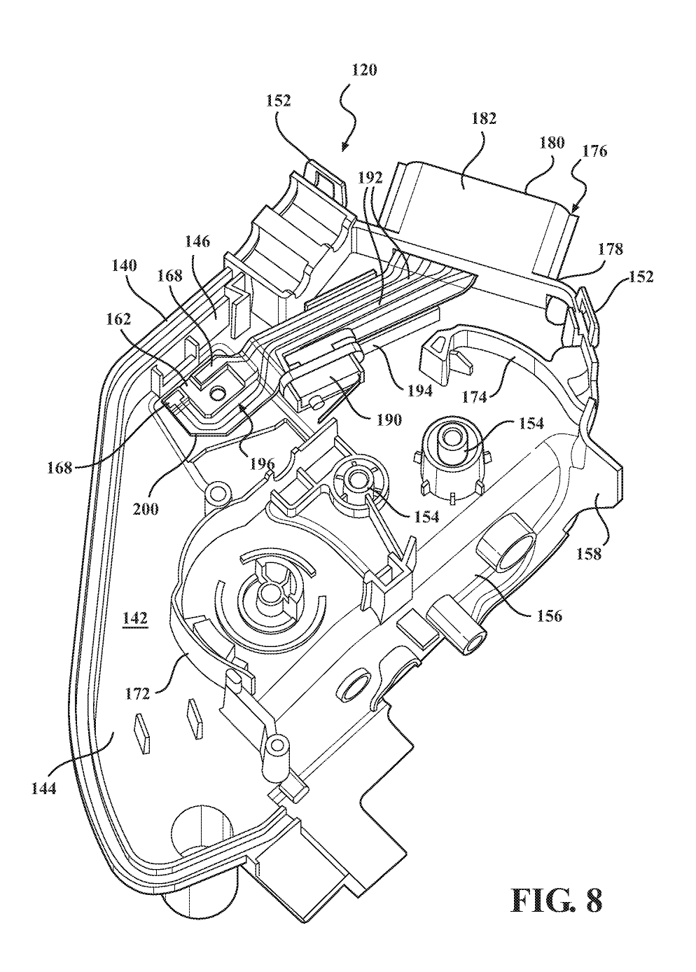

As best shown in FIG. 8, a switch 190 having a pair of switch terminals may also engage the switch pads 170 of the switch platform 164 and be disposed on the switch platform 164. A plurality of traces 192 electrically connect to and extend along with upper surface 198 (i.e. trace substrate) from the switch platform 64 and the motor pads 68 of the motor platform 162 to the cartridge 196 terminals for interconnecting the motor and the switch 190 with the cartridge 196 terminals. As with the housing body 40 described above, the cartridge 196 can be a molded interconnect device (MID), in other words, an injection-molded thermoplastic part with integrated circuit traces 192. Specifically, the cartridge 196 and traces 192 can be manufactured by one-shot molding, or laser directed structuring in which the thermoplastic material of the cartridge 196 is doped with a metal-plastic additive which can be activated by a laser and metallized. It should be appreciated that the cartridge 196 and traces 192 of the housing assembly 120 may instead be formed by another type of molded interconnect device technology, such as, but not limited to a two-shot molding method with two different thermoplastic resins with only one being platable (e.g. used in the areas where traces 192 are desired) or laser direct removing (MIPTEC). Additionally, the traces 192 may also be formed using a protopaint or conductive material which can be sprayed or otherwise applied to the cartridge 196. As with the doped thermoplastic described above, the conductive material or protopaint may then be activated with a laser and metallized.

The housing body 140 further includes a first intermediate wall 172 extending upwardly from the top surface 144 of the housing body 140 and extending circuitously from the shoulder to the cartridge 196. A second intermediate wall 174 extends upwardly from the top surface 144 of the housing body 140 and extends from the first peripheral wall 146 adjacent the connector 176.

A cap (not shown) may also be adapted to engage the housing body 140 and the locking tabs 152 for moving the switch terminals into engagement with the switch pads 170 and for securing the motor terminals against the motor pads 168 and for covering the components of the power operated device. Therefore, it may not be necessary to use a solder process in order to electrically connect the motor and/or switch 190 to the traces 192.

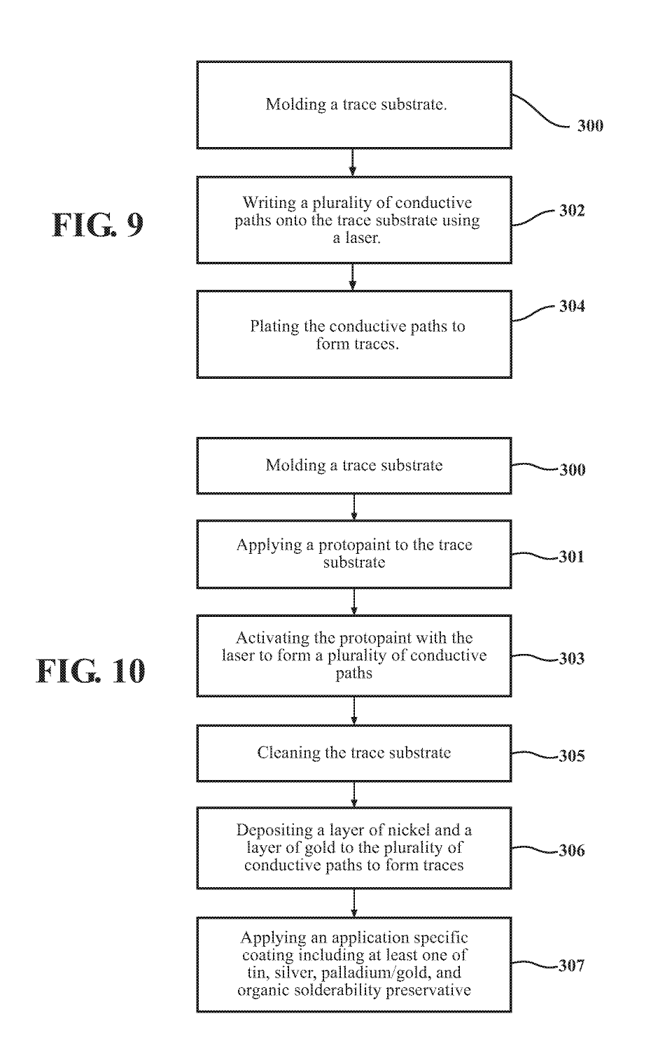

As illustrated in FIGS. 9 and 10, a method of manufacturing the housing of the power operated device is also disclosed. The method includes the step of 300 molding the trace substrate. The trace substrate may be molded using a resin capable of being activated by a laser. However, it should be appreciated that if protopaint 93 or another conductive material is applied, the method may include an additional step of 301 applying the protopaint 93 to the trace substrate. In such a case, the trace substrate would not be required to be capable of being activated by a laser. According to an aspect, the trace substrate may be defined by the housing body 40 (e.g., top surface 44), but it should be appreciated that the trace substrate may also be defined by another part, such as the cartridge 196 (e.g., upper surface 198) that can be attached or fitted to the housing body 140, for example. The resin used may be a commercially available thermoplast provided with additives. The method proceeds by 302 writing a plurality of conductive paths (i.e. desired interconnect pattern) onto the trace substrate using a laser. In the case of protopaint 93, the areas which have the protopaint 93 applied are activated by the laser. So, the step of 302 writing a plurality of conductive paths onto the trace substrate using a laser can be further defined as 303 activating the protopaint with a laser to form a plurality of conductive paths. The exposure to the laser creates metallic seeds through a physical-chemical reaction (i.e. activation). Additionally, the laser may also produce a micro-rough surface on which a metallic material (e.g. copper) may be firmly anchored. According to an aspect, the conductive paths or desired interconnect pattern may be provided from computer automated design (CAD) data defining the desired layout of paths on the trace substrate. Accordingly, the circuit pattern or layout of the conductive paths can be changed by simply changing the CAD data. The next step of the method is 304 plating the conductive paths to form traces 92, 192. This step is also known as metallization. According to an aspect, the metallization may also include a cleaning step which is followed by additive build-up in copper baths. So, the method can additionally include the step of 305 cleaning the trace substrate. The build-up may occur at a rate of 8-12 μm per hour, for example. According to another aspect, the metallization be further defined as 306 depositing a layer of nickel and a layer of gold to the plurality of conductive paths to form traces. Additionally, application specific coatings such as Sn (tin), Ag (silver), Pd/Au (palladium/gold), and/or organic solderability preservative (OSP) can be applied. So the method may also include the step of 306 applying an application specific coating including at least one of tin, silver, palladium/gold, and organic solderability preservative. The resulting housing assembly 20, 120 is a molded interconnect device (MID) which includes the traces 92, 192 embedded on to the trace substrate. Because many laser-activatable plastics or resins have a high level of heat resistance, reflow-soldering and surface-mount technology processes may be used.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. Those skilled in the art will recognize that concepts disclosed in association with an example switching system can likewise be implemented into many other systems to control one or more operations and/or functions.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

Obviously, many modifications and variations of the present invention are possible in light of the above teachings and may be practiced otherwise than as specifically described while within the scope of the appended claims.

What is claimed is:

1. A housing assembly for a power operated device comprising:
a housing body for securing and attaching components of the power operated device;
at least one contact platform coupled to said housing body;
a connector attached to said housing body and defining an inner cavity and including a plurality of connector terminals disposed in said inner cavity; and
a trace substrate coupled to said housing body and including a plurality of traces formed on said trace substrate and electrically connected to and extending from said at least one contact platform to said connector.

2. A housing assembly as set forth in claim 1, wherein said housing body defines a top surface and a bottom surface opposite said top surface and said top surface comprises said trace substrate.

3. A housing assembly as set forth in claim 2, wherein said contact platforms extend upwardly from said top surface of said housing body.

4. A housing assembly as set forth in claim 1, wherein said trace substrate comprises a cartridge disposed on said housing body.

5. A housing assembly as set forth in claim 4, wherein said cartridge has an upper surface and a lower surface and said contact platforms are disposed on said upper surface of said cartridge.

6. A housing assembly as set forth in claim 1, wherein said at least one contact platform includes at least one of a motor platform and a switch platform.

7. A housing assembly as set forth in claim 1, wherein said plurality of traces are formed using laser directed structuring.

8. A housing assembly as set forth in claim 1, wherein said plurality of traces are formed using microscopic integrated processing technology.

9. A housing assembly as set forth in claim 1, wherein said plurality of traces are formed using a protopaint applied to said trace substrate.

10. A housing assembly for a power operated device comprising:
a trace substrate including a plurality of traces formed on said trace substrate by a molded interconnect technology;
a connector coupled to said trace substrate and including a plurality of connector terminals;
a motor platform coupled to said trace substrate for coupling to a motor adapted to electrically connect to said plurality of traces to move components of the power operated device; and
a switch platform coupled to said trace substrate for coupling to a switch adapted to electrically connect to said plurality of traces to detect one of movement and position of the components.

11. A housing assembly as set forth in claim 10, further including a housing body defining a top surface and a bottom surface opposite said top surface and wherein said top surface comprises said trace substrate.

12. A housing assembly as set forth in claim 10, wherein said trace substrate comprises a cartridge.

13. A housing assembly as set forth in claim 10, wherein said molded interconnect technology includes laser directed structuring.

14. A housing assembly as set forth in claim 10, wherein said molded interconnect technology includes microscopic integrated processing technology.

15. A housing assembly as set forth in claim 10, wherein said molded interconnect technology includes the application of protopaint to said trace substrate.

16. A method of manufacturing a housing assembly of a power operated device comprising;
molding a trace substrate,
writing a plurality of conductive paths onto the trace substrate using a laser, and
plating the plurality of conductive paths to form traces.

17. A method as set forth in claim 16, further including the step of applying a protopaint to the trace substrate and wherein the step of writing a plurality of conductive paths onto the trace substrate using a laser includes activating the protopaint with the laser to form a plurality of conductive paths.

18. A method as set forth in claim 16, further including the step of cleaning the trace substrate.

19. A method as set forth in claim 16, wherein the step of plating the conductive paths to form traces is further defined as depositing a layer of nickel and a layer of gold to the plurality of conductive paths to form traces.

20. A method as set forth in claim 16, further including the step of applying an application specific coating including at least one of tin, silver, palladium/gold, and organic solderability preservative.
